(19) United States
(12) Patent Application Publication
(10) Pub. No.: US 2025/0089371 A1
(43) Pub. Date: Mar. 13, 2025

(54) DRIVING CIRCUIT MOUNTING FILM

(71) Applicant: Samsung Electronics Co., Ltd., Suwon-si (KR)

(72) Inventors: KYOUNGSUK YANG, Suwon-si (KR); SEONGHO SHIN, Suwon-si (KR); MI-NA CHOI, Suwon-si (KR); JU-YOUN CHOI, Suwon-si (KR)

(21) Appl. No.: 18/626,413

(22) Filed: Apr. 4, 2024

(30) Foreign Application Priority Data
Sep. 7, 2023 (KR) 10-2023-0119105

(51) Int. Cl. H01L 27/12; G09G 3/00

(52) U.S. Cl. CPC H10D 86/60; G09G 3/006; H10D 86/441; G09G 2330/12

(57) ABSTRACT

A driving circuit mounting film according to an embodiment includes a base film having a first surface and a second surface facing each other, a driving circuit part positioned on the first surface of the base film, a plurality of signal lines positioned on the first surface of the base film, and a test signal pad part positioned on the second surface of the base film, wherein the test signal pad part includes a plurality of openings, and at least part of the plurality of openings overlaps with at least part of the plurality of first signal lines.

### CROSS-REFERENCE TO RELATED APPLICATION

This application claims priority under 35 U.S.C. § 119 to and the benefit of Korean Patent Application No. 10-2023-0119105, filed in the Korean Intellectual Property Office on Sep. 7, 2023, the entire contents of which are incorporated herein by reference.

### BACKGROUND OF THE DISCLOSURE

### (a) Field of the Disclosure

This disclosure relates to a driving circuit mounting film.

### 2. Description of the Related Art

In order to transmit a driving signal to a display device, a plurality of signal lines of the display device may be connected to a chip-on-film (COF).

As the resolution of the display device increases, the number of the signal lines connected to the chip-on-film increases, and the number of the signal lines formed on the chip-on-film also increases.

Meanwhile, a test signal pad part for applying a test signal after connecting the chip-on-film to the display device may be positioned on the chip-on-film.

As the number of the signal lines positioned on the chip-on-film increases, the area occupied by the test signal pad and the signal lines increases, and then the size of the chip-on-film increases.

### SUMMARY OF THE DISCLOSURE

Embodiments are intended to provide a driving circuit mounting film that may prevent the area occupied by the test signal pad part and the signal line from increasing and reduce a parasitic capacitance between the test signal pad part and the signal line.

However, the object to be achieved by the embodiments is not limited to the above-mentioned objects, but may be variously expanded without departing from the technical spirit of this disclosure.

A driving circuit mounting film according to an embodiment includes a base film having a first surface and a second surface facing away from each other, a driving circuit part positioned on the first surface of the base film, a plurality of signal lines positioned on the first surface of the base film, and a test signal pad part positioned on the second surface of the base film, wherein the test signal pad part includes a plurality of openings, and at least part of the plurality of openings overlaps with at least part of the plurality of signal lines.

According to embodiments, the driving circuit mounting film that may prevent the area occupied by the test signal pad part and the signal line from increasing and reduce a parasitic capacitance between the test signal pad part and the signal line may be provided.

However, the effects of the embodiments are not limited to the above-described effects, and may be expanded in various ways in the range of the ideas and the areas of this disclosure.

### BRIEF DESCRIPTION OF THE DRAWINGS

FIG. 1 is a top plan view of a display device including a plurality of driving circuit mounting films according to an example embodiment.

FIG. 2 is a top plan view of a first surface of a driving circuit mounting film according to an example embodiment.

FIG. 3 is a top plan view of a second surface of a driving circuit mounting film according to an example embodiment.

FIG. 4 is a cross-sectional view taken along a line I-I′ in FIG. 2.

FIG. 5 is a top plan view of a test signal pad part of a driving circuit mounting film according to an example embodiment.

FIG. 6 is a top plan view showing a portion of a test signal pad part and a plurality of signal lines of a driving circuit mounting film according to an example embodiment.

FIG. 7 is a top plan view of a test signal pad part of a driving circuit mounting film according to another example embodiment.

FIG. 8 is a top plan view of parts of a test signal pad part and a plurality of signal lines of a driving circuit mounting film according to another example embodiment.

FIG. 9 is a top plan view of a test signal pad part of a driving circuit mounting film according to another example embodiment.

FIG. 10 is a top plan view showing a portion of a test signal pad part and a plurality of signal lines of a driving circuit mounting film according to another example embodiment.

### DETAILED DESCRIPTION

The embodiments will be described more fully hereinafter with reference to the accompanying drawings, in which embodiments are shown. As those skilled in the art would realize, the described embodiments may be modified in various different ways, all without departing from the spirit or scope of the embodiments.

In order to clarify the embodiments, parts that are not connected with the description will be omitted, and the same elements or equivalents are referred to by the same reference numerals throughout the specification.

Further, the accompanying drawings are provided only in order to allow embodiments disclosed in the present specification to be easily understood, and are not to be interpreted as limiting the spirit disclosed in the present specification, and it is to be understood that the embodiments include all modifications, equivalents, and substitutions without departing from the scope and spirit of this disclosure.

Further, since sizes and thicknesses of constituent members shown in the accompanying drawings are arbitrarily given for better understanding and ease of description, the embodiments are not limited to the illustrated sizes and thicknesses. In the drawings, the thickness of layers, films, panels, regions, etc. are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” means when an object portion is viewed from above, and the phrase “on a cross-section” means when a cross-section taken by vertically cutting an object portion is viewed from the side.

In addition, in the specification, when referring to “connected to”, this does not only mean that two or more constituent elements are directly connected, but also that two or more constituent elements are electrically connected through other constituent elements as well as being indirectly connected and being physically connected, or it may mean that they are referred to by different names according to a position or function, but are integrated.

Hereinafter, various embodiments and variations are described in detail with reference to accompanying drawings.

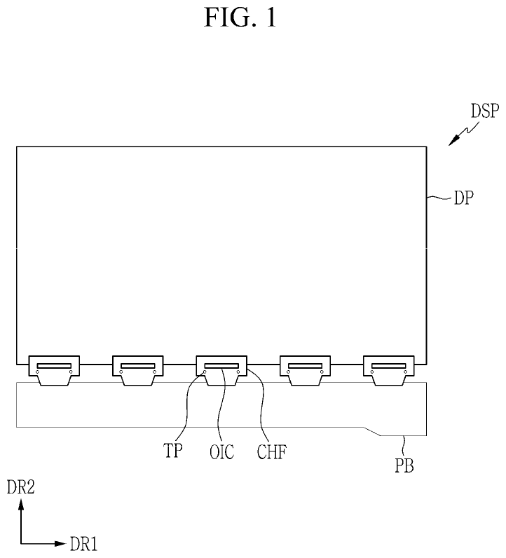

A display device DSP including a plurality of driving circuit mounting films according to an embodiment is described with reference to FIG. 1. FIG. 1 is a top plan view of a display device including a plurality of driving circuit mounting films according to an embodiment.

Referring to FIG. 1, the display device DSP including a plurality of driving circuit mounting films according to an embodiment may include a display panel DP including a plurality of pixels, a plurality of driving circuit mounting films CHF connected to the display panel DP, and a driving circuit board PB connected to the plurality of driving circuit mounting films CHF.

Each of the driving circuit mounting films CHF may include a driving circuit part OIC and a test signal pad part TP.

The display panel DP may extend in the first direction DR1 and the second direction DR2 different from the first direction DR1, and the plurality of driving circuit mounting films CHF may be arranged along the first direction DR1 on one edge of the display panel DP. However, the embodiment is not limited thereto.

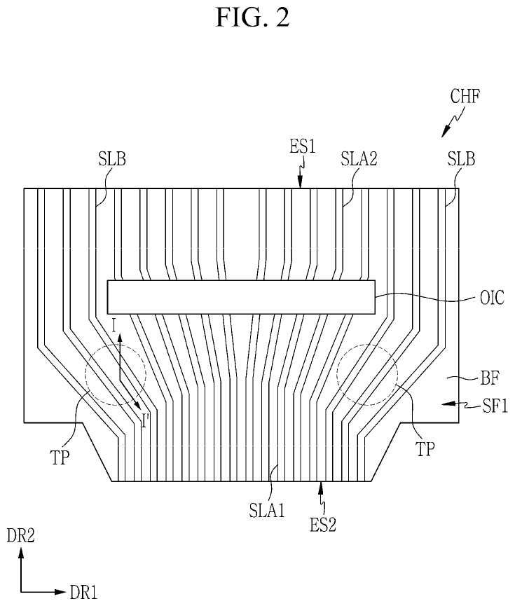

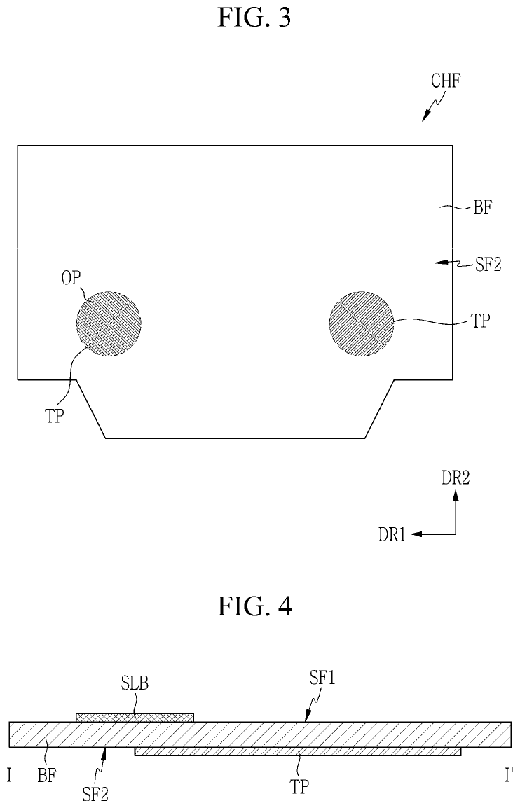

The driving circuit mounting film CHF according to an embodiment is described with reference to FIG. 2 to FIG. 4. FIG. 2 is a top plan view of a first surface of a driving circuit mounting film according to an embodiment, FIG. 3 is a top plan view of a second surface of a driving circuit mounting film according to an embodiment, and FIG. 4 is a cross-sectional view taken along a line I-l′ in FIG. 2.

The base film BF of the driving circuit mounting film CHF according to one embodiment may include a first surface SF1 and a second surface SF2 facing away from one another. For example, the first surface SF1 and the second surface SF2 may be on opposite sides of the base film BF.

Referring to FIG. 2, the driving circuit mounting film CHF may include a driving circuit part OIC positioned on the first surface SF1 of the base film BF, a plurality of first signal lines SLA1 and a plurality of second signal lines SLA2, which are connected to the driving circuit part OIC, and a plurality of third signal lines SLB, which are not connected to the driving circuit part OIC.

The plurality of first signal lines SLA1 may be connected between the display panel DP and the driving circuit part OIC of FIG. 1, and the plurality of second signal lines SLA2 may be connected between the driving circuit part OIC and the driving circuit board PB of FIG. 1. For example, the plurality of first signal lines SLA1 may extend between the driving circuit part OIC and the second end side ES2, and the plurality of second signal lines SLA2 may extend between the driving circuit part OIC and the first end side ES1.

Referring to FIG. 3, the driving circuit mounting film CHF may include a test signal pad part TP positioned on the second surface SF2 of the base film BF, and the test signal pad part TP may include a plurality of openings OP.

Referring to FIG. 4, a portion among the plurality of signal lines SLA1, SLA2, and SLB positioned on the first surface SF1 of the base film BF of the driving circuit mounting film CHF may overlap the test signal pad part TP positioned on the second surface SF2 of the base film BF of the driving circuit mounting film CHF.

By positioning the test signal pad part TP on the second surface SF2 of the base film BF to overlap the portion of the plurality of signal lines SLA1, SLA2, and SLB positioned on the first surface SF1 of the base film BF of the driving circuit mounting film CHF, on a plane viewing the driving circuit mounting film CHF from above, the region where the test signal pad part TP is positioned and the region where the plurality of signal lines SLA1, SLA2, and SLB are positioned may overlap. Therefore, compared to a case where a plurality of signal lines SLA1, SLA2, and SLB and a test signal pad part TP are formed together on the same surface of the base film BF of the driving circuit mounting film CHF, the size of the driving circuit mounting film CHF may be reduced.

Meanwhile, by overlapping some of the plurality of signal lines SLA1, SLA2, and SLB and the test signal pad part TP with each other and with the base film BF of the driving circuit mounting film CHF in between, a parasitic capacitance may occur, and a static electricity charge may move inside the display panel DP due to unnecessary parasitic capacitance.

However, as described previously, according to the embodiment, the test signal pad part TP of the driving circuit mounting film CHF includes the plurality of openings OP, the overlap area of the test signal pad part TP and some of the plurality of signal lines SLA1, SLA2, and SLB, which overlap each other with the base film BF in between, may be reduced. Accordingly, it is possible to reduce the parasitic capacitance that may occur when some of the plurality of signal lines SLA1, SLA2, and SLB and the test signal pad part TP overlap with each other across the base film BF of the driving circuit mounting film CHF.

According to the driving circuit mounting film CHF according to an embodiment, as some of the plurality of signal lines SLA1, SLA2, and SLB positioned on the first surface SF1 of the base film BF of the driving circuit mounting film CHF overlap the test signal pad parts TP positioned on the second surface SF2 of the base film BF of the driving circuit mounting film CHF, and the test signal pad part TP include the plurality of openings OP, while preventing the size of the driving circuit mounting film CHF from increasing, the parasitic capacitance that may occur when some of the plurality of signal lines SLA1, SLA2, and SLB and the test signal pad part TP overlap with each other across the base film BF of the driving circuit mounting film CHF may be reduced.

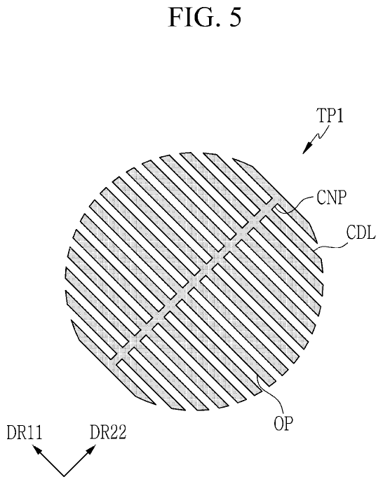

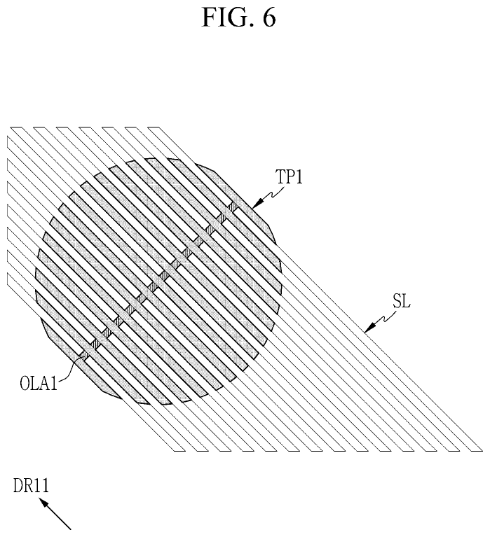

The test signal pad part of the driving circuit mounting film according to an embodiment, and the overlapping portion between the test signal pad part and the plurality of signal lines are described with reference to FIG. 5 and FIG. 6. FIG. 5 is a top plan view of a test signal pad part of a driving circuit mounting film according to an example embodiment. FIG. 6 is a top plan view showing a portion of a test signal pad part and a plurality of signal lines of a driving circuit mounting film according to an example embodiment. The test signal pad parts TP1 of FIG. 5 and FIG. 6 may correspond to the test signal pad parts TP of FIG. 2 through FIG. 4.

Referring to FIG. 5, the test signal pad part TP1 of the driving circuit mounting film according to one embodiment may have a roughly circular planar shape. However, the embodiment is not limited to this.

The test signal pad part TP1 of the driving circuit mounting film according to the embodiment may include a plurality of branch portions CDL spaced apart by the plurality of openings OP and extending lengthwise along a third direction DR11, and a stem portion CNP extending in a fourth direction DR22 different from the third direction DR11. The stem portion CNP may connect the plurality of branch portions CDL to each other. For example, each of the plurality of branch portions CDL may contact the stem portion CNP. In example embodiments, the plurality of branch portions CDL may be perpendicular to the stem portion CNP, although embodiments are not limited thereto.

The width of each of the plurality of branch portions CDL may be substantially equal to or smaller than the interval between two adjacent signal lines SL among the plurality of signal lines SL, and the width of each of the plurality of openings OP may be substantially equal to or larger than the width of a corresponding one of the plurality of signal lines SL.

Referring to FIG. 6, the plurality of signal lines SL overlapping the test signal pad part TP1 among the plurality of signal lines SL positioned on the first surface SF1 of the base film BF may extend along the third direction DR11 that the plurality of branch portions CDL of the test signal pad part TP1 extend. For example, the plurality of branch portions CDL may extend substantially parallel to the plurality of signal lines SL.

As above-described, the width of the plurality of branch portions CDL of the test signal pad part TP1 may be approximately equal to or smaller than the interval between two adjacent signal lines SL among the plurality of signal lines SL, and the width of the plurality of openings OP of the test signal pad part TP1 may be equal to or larger than the width of the plurality of signal lines SL.

Therefore, the plurality of branch portions CDL of the test signal pad part TP1 may extend along between two adjacent signal lines SL, and the plurality of openings OP of the test signal pad part TP1 may extend along the plurality of branch portions CDL.

Therefore, the plurality of branch portions CDL of the test signal pad part TP1 may not overlap with the plurality of signal lines SL, and only a portion of the stem portion CNP of the test signal pad part TP1 may overlap with the plurality of signal lines SL. The plurality of signal lines SL may be a part of the plurality of signal lines SLA1, SLA2, and SLB positioned on the first surface SF1 of the base film BF.

The first overlapping region OLA1, where the test signal pad part TP1 and the plurality of signal lines SL overlap each other, is a region where a part of the stem portion CNP of the test signal pad part TP1 overlaps the plurality of signal lines SL.

As above-described, according to the embodiment, as the test signal pad part TP1 includes the plurality of branch portions CDL spaced apart by the plurality of openings OP and extending along the third direction DR11 and the stem portion CNP extending in the fourth direction DR22 different from the first direction DR1 that the plurality of branch portions CDL extends and connecting the plurality of branch portions CDL to each other, since the first overlapping region OLA1 where the test signal pad part TP1 and the plurality of signal lines SL overlap to each other is the region where the part of the stem portion CNP of the test signal pad part TP1 and the plurality of signal lines SL overlap, compared to a case where the test signal pad part is formed in a solid circular plate shape, the area of the first overlapping region OLA1 where the test signal pad part TP1 and the plurality of signal lines SL overlap each other may be relatively reduced.

Through this, it is possible to reduce the parasitic capacitance that may occur when the test signal pad part TP1 and the plurality of signal lines SL overlap with each other across the base film BF of the driving circuit mounting film CHF.

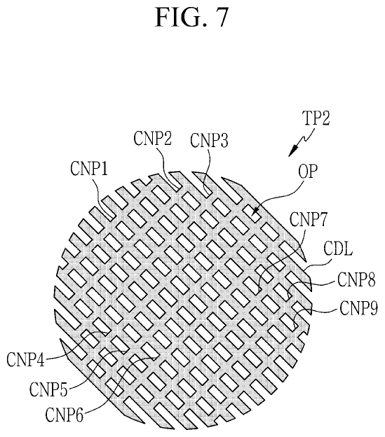

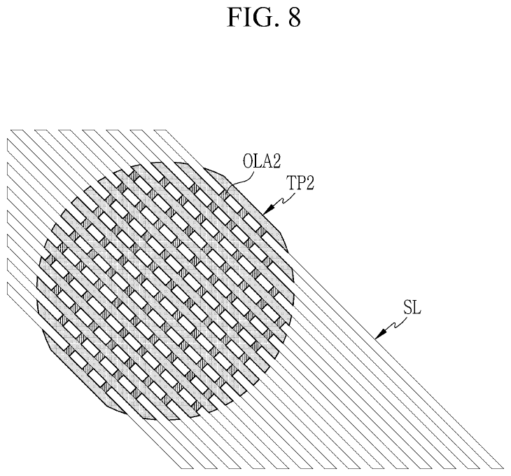

The test signal pad part, and the overlapping part of the test signal pad part and the plurality of signal lines of the driving circuit mounting film according to the embodiment are described with reference to FIG. 7 and FIG. 8. FIG. 7 is a top plan view of a test signal pad part of a driving circuit mounting film according to another example embodiment. FIG. 8 is a top plan view of parts of a test signal pad part and a plurality of signal line of a driving circuit mounting film according to another example embodiment. The test signal pad parts TP2 of FIG. 7 and FIG. 8 may correspond to the test signal pad parts TP of FIG. 2 through FIG. 4.

Referring to FIG. 7, the test signal pad part TP2 of the driving circuit mounting film according to one embodiment may have an approximately circular planar shape. However, the embodiment is not limited thereto.

The test signal pad part TP2 of the driving circuit mounting film according to the embodiment may include a plurality of branch portions CDL spaced by a plurality of openings OP and extending along the third direction DR11, and a plurality of stem portions CNP1, CNP2, CNP3, CNP4, CNP5, CNP6, CNP7, CNP8, and CNP9 extending in the fourth direction DR22 different from the third direction DR11 and connecting the plurality of branch portions CDL to each other. The plurality of stem portions CNP1, CNP2, CNP3, CNP4, CNP5, CNP6, CNP7, CNP8, and CNP9 may be substantially parallel to each other.

The width of each of the plurality of branch portions CDL may be substantially equal to or smaller than the interval between two adjacent signal lines SL among the plurality of signal lines SL, and the width of each of the plurality of openings OP may be substantially equal to or larger than the width of the plurality of signal lines SL.

Referring to FIG. 8, among the plurality of signal lines SL positioned in the first surface SF1 of the base film BF, the plurality of signal lines SL overlapping the test signal pad part TP2 may extend along the third direction DR11 that the plurality of branch portions CDL of the test signal pad part TP1 extend.

As described previously, the width of the plurality of branch portions CDL of the test signal pad part TP2 may be substantially equal to or smaller than the interval between two adjacent signal lines SL among the plurality of signal lines SL, and the width of the plurality of openings OP of the test signal pad part TP2 may be substantially equal to or larger than the width of the plurality of signal lines SL.

Therefore, the plurality of branch portions CDL of the test signal pad part TP2 extend along between two adjacent signal lines SL, and the plurality of openings OP of the test signal pad part TP2 may extend along the plurality of branch portions CDL. For example, the plurality of branch portions CDL of the test signal pad part TP2 may extend substantially parallel to the plurality of signal lines SL.

Therefore, the plurality of branch portions CDL of the test signal pad part TP2 may not overlap with the plurality of signal lines SL, and only a part of each of the plurality of stem portions CNP1, CNP2, CNP3, CNP4, CNP5, CNP6, CNP7, CNP8, and CNP9 of the test signal pad part TP2 may overlap the plurality of signal lines SL. The plurality of signal lines SL may be a part of the plurality of signal lines SLA1, SLA2, and SLB positioned on the first surface SF1 of the base film BF.

The second overlapping region OLA2, where test signal pad part TP2 and plurality of signal lines SL overlap each other, is a region where each portion of the plurality of stem portions CNP1, CNP2, CNP3, CNP4, CNP5, CNP6, CNP7, CNP8, and CNP9 of the test signal pad part TP2 overlaps the plurality of signal lines SL.

As above-described, according to the embodiment, the test signal pad part TP2 includes the plurality of branch portions CDL spaced by the plurality of openings OP and extending along the third direction DR11, and the plurality of stem portions CNP1, CNP2, CNP3, CNP4, CNP5, CNP6, CNP7, CNP8, and CNP9 extending in the fourth direction DR22 different from the third direction DR11 and connecting the plurality of branch portions CDL to each other, since the second overlapping region OLA2, where test signal pad part TP2 and plurality of signal lines SL overlap each other, is a region where each portion of the plurality of stem portions CNP1, CNP2, CNP3, CNP4, CNP5, CNP6, CNP7, CNP8, and CNP9 of the test signal pad part TP2 overlap the plurality of signal lines SL, compared to a case where the test signal pad part is formed in a solid circular plate shape, the area of the second overlapping region OLA2 where the test signal pad part TP2 and the plurality of signal lines SL overlap each other may be relatively reduced.

Through this, it is possible to reduce the parasitic capacitance that may occur when the test signal pad part TP2 and the plurality of signal lines SL overlap with each other across the base film BF of the driving circuit mounting film CHF.

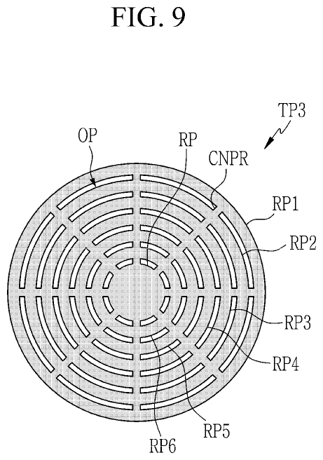

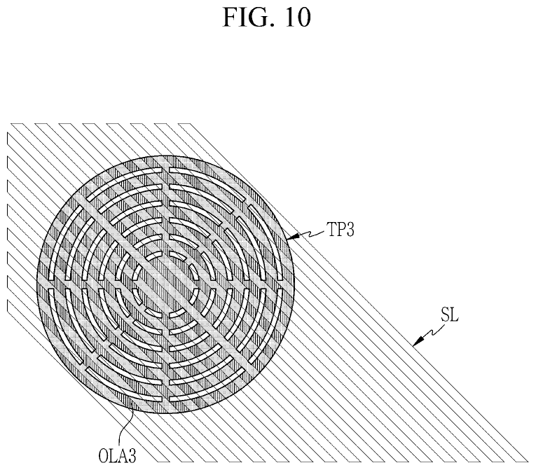

The test signal pad part, and the overlapping part of the test signal pad part and the plurality of signal lines of the driving circuit mounting film according to the embodiment are described with reference to FIG. 9 and FIG. 10. FIG. 9 is a top plan view of a test signal pad part of a driving circuit mounting film according to another example embodiment. FIG. 10 is a top plan view showing a portion of a test signal pad part and a plurality of signal lines of a driving circuit mounting film according to another example embodiment. The test signal pad parts TP3 of FIG. 9 and FIG. 10 may correspond to the test signal pad parts TP of FIG. 2 through FIG. 4.

Referring to FIG. 9, the test signal pad part TP3 of the driving circuit mounting film according to one embodiment may have an approximately circular planar shape. However, the embodiment is not limited thereto.

The test signal pad part TP3 of the driving circuit mounting film according to the embodiment may include a circular central portion RP positioned in the center, a plurality of branch portions RP1, RP2, RP3, RP4, RP5, and RP6 spaced apart by the plurality of openings OP and having a ring shape, and a plurality of stem portions CNPR connecting the plurality of branch portions RP1, RP2, RP3, RP4, RP5, and RP6 and extending in different directions from the central portion RP to the outermost branch portion RP1.

At least one of the plurality of stem portions CNPR may extend in the first direction DR1 parallel to the direction in which the plurality of signal lines SL extends, and the width of the plurality of stem portions CNPR may be smaller than the interval between two adjacent signal lines SL.

Referring to FIG. 10, among the plurality of signal lines SL positioned on the first surface SF1 of the base film BF, the plurality of signal lines SL overlapping the test signal pad part TP3 may extend along the third direction DR11. The plurality of signal lines SL may be a part of the plurality of signal lines SLA1, SLA2, and SLB positioned on the first surface SF1 of the base film BF.

The third overlapping region OLA3, where the test signal pad part TP3 and the plurality of signal lines SL overlap each other, may be a region corresponding to a part of the plurality of branch portions CNPR of the test signal pad part TP3, a region corresponding to a part of the central portion RP, and a region corresponding to a part of each of the plurality of stem portions RP1, RP2, RP3, RP4, RP5, and RP6.

As above-described, according to the embodiment, the test signal pad part TP3 may include the circular central portion RP, the plurality of branch portions RP1, RP2, RP3, RP4, RP5, and RP6 spaced apart by the plurality of openings OP and having the ring shape, and the plurality of stem portions CNPR connecting the plurality of branch portions RP1, RP2, RP3, RP4, RP5, and RP6 and extending in the different directions from the central portion RP to the outermost branch portion RP1, at least one of the plurality of stem portions of CNPR may extend in the first direction DR1 parallel to the direction in which the plurality of signal lines SL extends, and the width of the plurality of stem portions CNPR may be smaller than the interval between two adjacent signal lines SL.

Therefore, the third overlapping region OLA3, where the test signal pad part TP3 and the plurality of signal lines SL overlap each other, may be a region corresponding to a portion of the plurality of stem portions CNPR of the test signal pad part TP3 overlapping the test signal pad part TP3, a region corresponding to a part of the central portion RP, and a region corresponding to a part of each of the plurality of branch portions RP1, RP2, RP3, RP4, RP5, and RP6. Therefore, compared to a case where the test signal pad part is formed in a solid circular plate shape, the area of the third overlapping region OLA3 where the plurality of signal lines SL overlap each other may be relatively reduced.

Through this, it is possible to reduce the parasitic capacitance that may occur when the test signal pad part TP3 and the plurality of signal lines SL overlap each other with the base film BF of the driving circuit mounting film CHF therebetween.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

### DESCRIPTION OF SYMBOLS

DP: display panel
DSP: display device
CHF: circuit mounting film
OIC: driving circuit part
TP, TP1, TP2, TP3: test signal pad part
BF: base film
OP: opening
CDL, RP1, RP2, RP3, RP4, RP5, RP6: branch portion
CNP, CNP1, CNP2, CNP3, CNP4, CNP5, CNP6, CNP7, CNP8, CNP9, CNPR: stem portion
OLA1, OLA2, OLA3: overlapping region
SLA1, SLA2, SLB, SL: signal line

What is claimed is:

1. A driving circuit mounting film comprising:
a base film having a first surface and a second surface facing away from each other,
a driving circuit part positioned on the first surface of the base film,
a plurality of signal lines positioned on the first surface of the base film, and
a test signal pad part positioned on the second surface of the base film,
wherein the test signal pad part includes a plurality of openings, and
wherein at least part of the plurality of openings overlaps with at least part of the plurality of signal lines.

2. The driving circuit mounting film of claim 1, wherein the test signal pad part includes a plurality of branch portions extending substantially parallel to the plurality of signal lines.

3. The driving circuit mounting film of claim 2, wherein the test signal pad part includes a stem portion extending in a direction different from the plurality of branch portions and connecting the plurality of branch portions.

4. The driving circuit mounting film of claim 3, wherein a width of each of the plurality of opening of the test signal pad part is substantially equal to or wider than a width of each of the plurality of signal lines.

5. The driving circuit mounting film of claim 3, wherein the plurality of signal lines overlap at least part of the stem portion.

6. The driving circuit mounting film of claim 5, wherein the plurality of signal lines is connected to the driving circuit part.

7. The driving circuit mounting film of claim 5, wherein the plurality of signal lines include a signal line that is not connected to the driving circuit part.

8. The driving circuit mounting film of claim 3, wherein the plurality of branch portions are substantially parallel to each other.

9. The driving circuit mounting film of claim 8, wherein a width of each of the plurality of openings of the test signal pad part is substantially equal to or wider than a width of each of the plurality first signal lines.

10. The driving circuit mounting film of claim 9, wherein the plurality of signal lines overlap with at least a portion of the stem portion.

11. The driving circuit mounting film of claim 10, wherein the plurality of signal lines are connected to the driving circuit part.

12. The driving circuit mounting film of claim 10, wherein the plurality of signal lines include a signal line that is not connected to the driving circuit part.

13. The driving circuit mounting film of claim 1, wherein the test signal pad part includes a plurality of ring-shaped branch portions.

14. The driving circuit mounting film of claim 13, wherein the test signal pad part further includes a circular central portion positioned in the center.

15. The driving circuit mounting film of claim 14, wherein the test signal pad part includes a plurality of stem portions extending in different directions from the circular central portion toward the outside and connecting the plurality of ring-shaped branch portions.

16. The driving circuit mounting film of claim 15, wherein a portion of the plurality of stem portions of the test signal pad part is positioned between the plurality of signal lines.

17. The driving circuit mounting film of claim 16, wherein the plurality of signal lines are connected to the driving circuit part.

18. The driving circuit mounting film of claim 16, wherein the plurality of signal lines include a signal line that is not connected to the driving circuit part.
